(19) United States
(12) Patent Application Publication
(10) Pub. No.: US 2020/0236802 A1
(43) Pub. Date: Jul. 23, 2020

(54) CHASSIS HAVING SLIDING COVER

(71) Applicant: HONGFUJIN PRECISION ELECTRONICS (TIANJIN) CO.,LTD., Tianjin (CN)

(72) Inventors: CHIH-HUNG CHANG, New Taipei (TW); CHAO-KE WEI, New Taipei (TW); TZE-CHERN MAO, Neihu (TW); YEN-CHUN FU, New Taipei (TW)

(21) Appl. No.: 16/257,474

(22) Filed: Jan. 25, 2019

(30) Foreign Application Priority Data
Jan. 17, 2019 (CN) 201910045141.8

(51) Int. Cl. H05K 5/03; H05K 5/02

(52) U.S. Cl. CPC H05K 5/03; H05K 5/023; H05K 5/0239

(57) ABSTRACT

A chassis includes a case and a sliding cover mounted on the case. The case defines a receiving space configured to receive electronic equipment and cooling liquid. The sliding cover includes a sliding frame and a number of cover plates. The sliding frame is arranged in an opening of the receiving space. Each of the cover plates is slidably mounted in the sliding frame. The cover plates cooperatively seal the receiving space when the cover plates are not overlapped with each other in the sliding frame.

### FIELD

The subject matter herein generally relates to a chassis, and more particularly to a chassis having a sliding cover.

### BACKGROUND

Generally, a data center includes a plurality of servers, and each server includes a chassis and a plurality of electronic equipment, such as a hard disk and a CPU, disposed in the chassis. A cover of the chassis is generally fixed to a cabinet by a buckle. When the modules in the chassis need to be replaced or maintained, the entire cover needs to be removed to replace or maintain the module, which is inconvenient.

### BRIEF DESCRIPTION OF THE DRAWINGS

Implementations of the present disclosure will now be described, by way of embodiments, with reference to the attached figures.

FIG. 1 is an isometric view of a chassis including a sliding cover sealing the chassis.

FIG. 2 is similar to FIG. 1, but showing the sliding cover opening the chassis.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other word that “substantially” modifies, such that the component need not be exact. For example, “substantially cylindrical” means that the object resembles a cylinder, but can have one or more deviations from a true cylinder. The term “comprising” means “including, but not necessarily limited to”; it specifically indicates open-ended inclusion or membership in a so-described combination, group, series and the like.

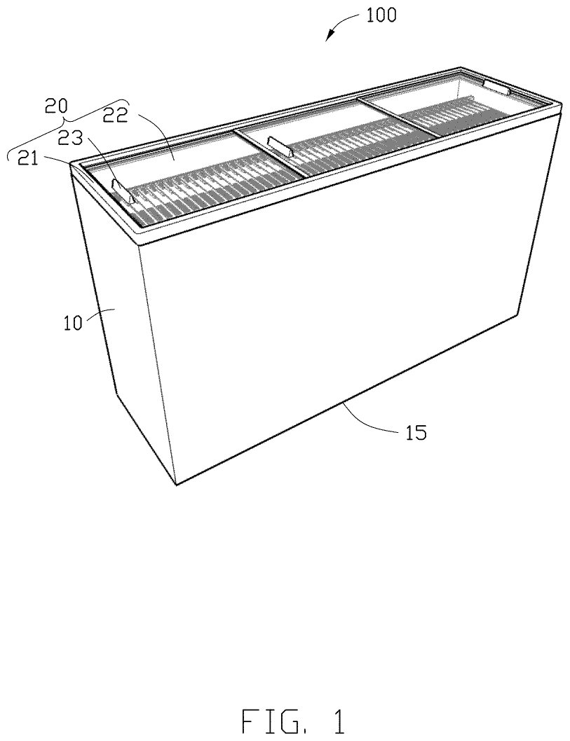

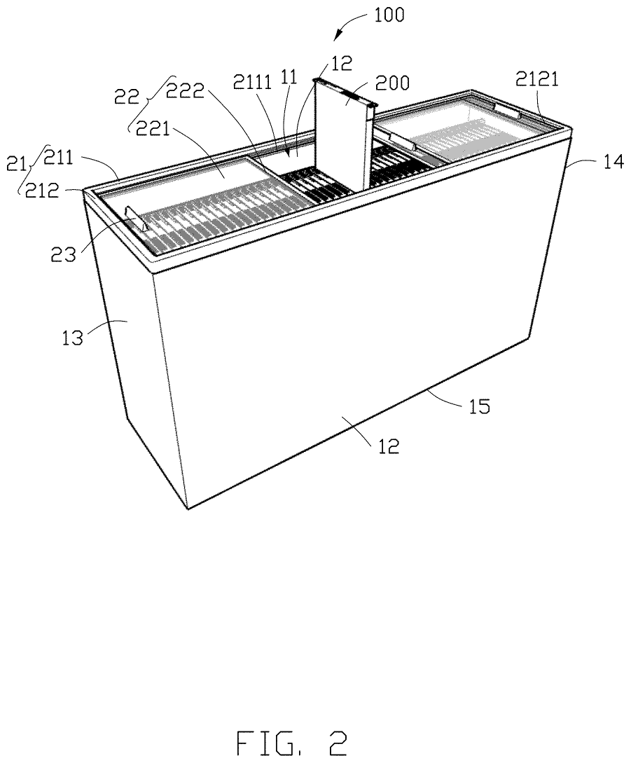

FIG. 1 shows an embodiment of a chassis 100 including a case 10 and a sliding cover 20 arranged on the case 10. The case 10 defines a receiving space 11 (shown in FIG. 2) configured to receive a plurality of electronic equipment 200 and cooling liquid. The electronic equipment may be a hard disk, a central processing unit, or other electronic device that requires heat dissipation. In one embodiment, the plurality of electronic equipment 200 is received and arranged side-by-side in the receiving space 11.

Referring to FIG. 2, the case 10 includes two first side plates 12, a second side panel 13, and a third side panel 14. The two first side plates 12 are substantially parallel to each other. The second side panel 13 is coupled between front ends of the two first side plates 12, and the third side panel 14 is coupled between rear ends of the two first side plates 12. A bottom plate 15 is coupled to the two first side plates 12, the second side panel 13, and the third side panel 14. The first side plates 12, the second side panel 13, the third side panel 14, and the bottom plate 15 cooperatively define the receiving space 11. The sliding cover 20 covers an opening of the receiving space 11.

The sliding cover 20 includes a sliding frame 21 and a plurality of cover plates 22. The sliding frame 21 is arranged at an opening of the receiving space 11. Each of the cover plates 22 is slidably arranged in the sliding frame 21, and the plurality of cover plates 22 are configured to seal the receiving space 11. In one embodiment, a quantity of the cover plates 22 is three, but is not limited thereto.

The sliding frame 21 includes two substantially parallel first side edges 211 and two substantially parallel second side edges 212. The two second side edges 211 are respectively coupled between a front end and a rear end of the two first side edges 211. The two first side edges 211 are respectively arranged on the two first side plates 12, and the two second side edges 212 are respectively arranged on the second side panel 13 and the third side panel 14. A side of each of the first side edges 211 facing the other side edge 211 defines a plurality of parallel and spaced apart sliding slots 2111. Opposite ends of each sliding groove 2111 extend to the corresponding second side edge 212. A side of each of the second side edges 212 facing the other second side edge 212 defines a plurality of sealing grooves 2121. The plurality of sealing grooves 2121 are spaced apart and parallel to each other. Opposite ends of each of the sealing grooves 2121 extend to the corresponding first side edge 211 and communicate with the corresponding sliding groove 2111. In one embodiment, an elastic sealing strip (not shown) is received in the sliding slots 2111 and the sealing grooves 2121.

The cover plates 22 are respectively slidably received in different sliding slots 2111. Each cover plate 22 includes a plate body 221 and a sealing band 222. The plate body 221 is slidably received in the corresponding sliding groove 2111. The sealing band 222 surrounds a periphery of the plate body 221.

When the cover plates 22 are not overlapped in the sliding frame 21, the cover plates 22 adjacent to the second side edges 212 extend into the sealing grooves 2121 to form a seal, and side edges of adjacent cover plates 22 cooperatively form a seal by the sealing band 222. Thus, the cover plates 22 cooperatively seal the receiving space 11.

In one embodiment, the plate body 221 is made of transparent glass so that the electronic equipment 200 can be viewed in the receiving space 11. In other embodiments, the plate body 221 may be a transparent acrylic board, a display that can display digital information, or other transparent material or metal material.

In one embodiment, the sliding cover 20 further includes a handle 23. The handle 23 is arranged on a side of the plate body 221 facing away from the receiving space 11.

In other embodiments, the sliding cover 20 may include a fixing member (not shown). The fixing member is configured to fix the cover plate 22 to the sliding frame 21 or to fix the plurality of cover plates 22 to each other when the plurality of cover plates 22 seal the receiving space 11. The fixing member may be a buckle.

In other embodiments, the sliding grooves 2111 and the sealing grooves 2121 may be omitted, and the two first side edges 211 may be provided with sliding rails for sliding the cover plates 22.

In one embodiment, the sliding frame 21 is arranged in the case 10. In other embodiments, the sliding frame 21 can be integrally formed with the case 10.

After the cover plates 22 are slid relative to each other, different openings of the receiving space 11 can effectively be exposed. Therefore, the entire sliding cover 20 is not required to be removed when the electronic equipment 200 needs to be replaced or maintained.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

1. A chassis comprising:
a case defining a receiving space configured to receive a plurality of electronic equipment and cooling liquid; and
a sliding cover mounted on the case; wherein:
the sliding cover comprises a sliding frame and a plurality of cover plates;
the sliding frame is arranged in an opening of the receiving space;
each of the plurality of cover plates is slidably mounted in the sliding frame;
the plurality of cover plates cooperatively seal the receiving space when the plurality of cover plates are not overlapped with each other in the sliding frame;
wherein each of the cover plates comprises a plate body, each of the cover plates is fixable to the sliding frame, and the plurality of cover plates are configured to be fixed together.

2. The chassis of claim 1, wherein:
the case comprises two first side plates, a second side panel, a third side panel, and a bottom panel;
the second side panel is coupled between a front end of each of the two first side plates;
the third side panel is coupled between a rear end of each of the two first side plates;
the bottom panel is coupled to each of the two first side plates, the second side panel, and the third side panel; and
the receiving space is cooperatively defined by the first side plates, the second side panel, the third side panel, and the bottom panel.

3. The chassis of claim 2, wherein:
the sliding frame comprises two first side edges and two second side edges;
the two second side edges are respectively coupled between a front end and a rear end of the two first side edges;
the two first side edges are respectively arranged on the two first side plates;
the two second side edges are respectively arranged on the second side panel and the third side panel;
a side of each of the two first side edges facing the other first side edge defines a plurality of sliding grooves, the plurality of sliding grooves being spaced apart and parallel to each other;
opposite ends of each of the plurality of sliding grooves extend to the corresponding one of the second side edges;
a side of each of the two second side edges facing another one of the second side edges defines a plurality of sealing grooves, the plurality of sealing grooves being spaced apart and parallel to each other;
opposite ends of each of the plurality of sealing grooves extend to a corresponding one of the first side edges and communicate with a corresponding one of the sliding grooves.

4. The chassis of claim 3, wherein:
the cover plate further comprises a sealing band;
the plate body is slidably received within the sliding grooves; and
the sealing band surrounds a periphery of the plate body.

5. (canceled)

6. The chassis of claim 1, wherein:
the sliding cover further comprises a handle;
the handle is mounted on a surface of the cover plate facing away from the receiving space.

7. (canceled)

8. The chassis of claim 1, wherein the sliding frame and the case are integrally formed.

9. The chassis of claim 3, wherein each of the cover plates is slidably received in a different sliding groove.

10. The chassis of claim 3, wherein at least two cover plates are slidably received in the same sliding groove.

11. A sliding cover configured to seal a receiving space of a case, the sliding cover comprising:
a sliding frame; and
a plurality of cover plates; wherein:
the sliding frame is arranged in an opening of the receiving space;
each of the plurality of cover plates is slidably mounted in the sliding frame; and
the plurality of cover plates cooperatively seal the receiving space when the plurality of cover plates are not overlapped with each other in the sliding frame-;
wherein each of the cover plates comprises a plate body, each of the cover plates is fixable to the sliding frame, and the plurality of cover plates are configured to be fixed together.

12. The sliding cover of claim 11, wherein:
the sliding frame comprises two first side edges and two second side edges;
the two second side edges are respectively coupled between a front end and a rear end of the two first side edges;
the two first side edges are respectively arranged on the two first side plates;
the two second side edges are respectively arranged on the second side panel and the third side panel;
a side of each of the two first side edges facing the other first side edge defines a plurality of sliding grooves, the plurality of sliding grooves being spaced apart and parallel to each other;
opposite ends of each of the plurality of sliding grooves extend to the corresponding one of the second side edges;
a side of each of the two second side edges facing another one of the second side edges defines a plurality of sealing grooves, the plurality of sealing grooves being spaced apart and parallel to each other;
opposite ends of each of the plurality of sealing grooves extend to a corresponding one of the first side edges and communicate with a corresponding one of the sliding grooves.

13. The sliding cover of claim 12, wherein:
the cover plate further comprises a sealing band;
the plate body is slidably received within the sliding grooves; and
the sealing band surrounds a periphery of the plate body.

14. (canceled)

15. The sliding cover of claim 11, wherein:
the sliding cover further comprises a handle;
the handle is mounted on a surface of the cover plate facing away from the receiving space.

16. (canceled)

17. The sliding cover of claim 11, wherein the sliding frame is integrally formed with the case.

18. The sliding cover of claim 11, wherein each of the cover plates is slidably received in a different sliding groove.

19. The sliding cover of claim 11, wherein at least two cover plates are slidably received in the same sliding groove.
